(19) United States
(12) Patent Application Publication
(10) Pub. No.: US 2026/0304974 A1
(43) Pub. Date: Oct. 1, 2026

(54) IMAGING SENSING DEVICE, SENSING SYSTEM, AND METHOD OF OPERATING THE IMAGING SYSTEM

(71) Applicant: SK hynix Inc., Icheon-si (KR)

(72) Inventor: Jong Chae KIM, Icheon-si (KR)

(21) Appl. No.: 19/297,812

(22) Filed: Aug. 12, 2025

(30) Foreign Application Priority Data
Mar. 25, 2025 (KR) 10-2025-0037767

(51) Int. Cl. H10F 39/00; H04N 25/773; H04N 25/78; H10F 30/225; H10F 77/00

(52) U.S. Cl. CPC H10F 39/8037; H04N 25/773; H04N 25/78; H10F 30/225; H10F 77/959

(57) ABSTRACT

An image sensing device is provided to comprise: a substrate; and a photodetector supported by the substrate and structured to comprise a first semiconductor area and a second semiconductor area surrounding the first semiconductor area, wherein the first semiconductor area includes a first sub-semiconductor area and a second sub-semiconductor area spaced apart from the first sub-semiconductor area, and wherein the first sub-semiconductor area and the second sub-semiconductor area are doped with a same conductivity type, and the second semiconductor area is doped with a different conductivity type from the first semiconductor area.

### PRIORITY AND CROSS-REFERENCE TO RELATED APPLICATION

This application claims priority to and the benefit of Korean Patent Application No. 10-2025-0037767, filed on Mar. 25, 2025, the disclosure of which is incorporated herein by reference in its entirety.

### TECHNICAL FIELD

Embodiments of the present disclosure relate to an image sensing device, an imaging system, and a method of operating the imaging system.

### BACKGROUND

Digital cameras and camcorders use image sensing devices that capture images and store them as electrical signals. Image sensing devices include sensors that decompose incident light into wavelengths and convert each component into electrical signals.

Recently, infrared sensors that detect light in the infrared (infra-red, IR) area are being studied to measure distances to objects, improve sensor sensitivity in low-light environments, or use them as biometric or security devices.

### SUMMARY

Some implementations of the disclosed technology provide an image sensing device, an imaging system, and a method of operating the imaging system with improved depth accuracy and reduced deterioration at a close range.

Some implementations of the disclosed technology provide an image sensing device, an imaging system, and a method of operating the imaging system with improved depth accuracy and deterioration at high brightness.

Various technical effects can be inferred from various embodiments.

In one aspect, an image sensing device is provided to comprise: a substrate; and a photodetector supported by the substrate and structured to comprise a first semiconductor area and a second semiconductor area surrounding the first semiconductor area, wherein the first semiconductor area includes a first sub-semiconductor area and a second sub-semiconductor area spaced apart from the first sub-semiconductor area, and wherein the first sub-semiconductor area and the second sub-semiconductor area are doped with a same conductivity type, and the second semiconductor area is doped with a different conductivity type from the first semiconductor area.

In another aspect, an imaging device is provided to comprise: an image sensing device including a pixel comprising a first photodetector and a second photodetector, and a switch coupled to the first photodetector to turn on or off a connection between the first and second photodetectors, wherein each of the first photodetector and the second photodetector comprises a first semiconductor area and a second semiconductor area surrounding the first semiconductor area, and the first semiconductor area includes a first sub-semiconductor area and a second sub-semiconductor area spaced apart from the first sub-semiconductor area; an image signal processor coupled to the image sensing device to receive pixel data from the pixel of the image sensing device and configured to process pixel data generated from the image sensing device; and a switch controller, wherein the pixel of the image sensing device further comprises an analog quenching transistor connected to the photodetector, and a switch turned on or off by the switch controller and arranged between the first photodetector and the second photodetector.

In another aspect, a method of operating an imaging device is provided. The method comprises: making a determination whether a distance to a target object is greater than or equal to a predetermined distance; turning off or on a switch disposed between a first sub-photodetector and a second sub-photodetector that are included in the imaging device based on the determination to operate either i) the first sub-photodetector only or ii) both of the first sub-photodetector and the second sub-photodetector; providing pulse signals generated from at least one of the first sub-photodetector or the second sub-photodetector to a read-out circuit to allow the read-out circuit to generate pixel data; and determining a distance to the target object based on the pixel data.

In another aspect, a method of operating an imaging device is provided. The method comprises: making a determination whether a illuminance of an environment external to the imaging device is higher or equal to a predetermined illuminance; turning off or on a switch disposed between a first sub-photodetector and a second sub-photodetector that are included in the imaging device based on the determination to operate either i) the first sub-photodetector only or ii) both of the first sub-photodetector and the second sub-photodetector; providing pulse signals generated from at least one of the first sub-photodetector or the second sub-photodetector to a read-out circuit; and generating pixel data based on the pulse signals.

According to the embodiment of the present disclosure, the single photodetector may include the two sub-photodetectors (the first sub-photodetector and the second sub-photodetector) such that the first semiconductor area of the photodetector includes a first sub-semiconductor area and a second sub-semiconductor area doped with the same type as each other. When the distance to the target object is short, in order to improve the accuracy of depth and the deterioration of dispersion, pixel data may be generated using only the first pulse signal generated from the first sub-photodetector, and when the distance to the target object is long, in order to maximize the output and optimize the long-distance output, pixel data may be generated using the pulse signals generated from each of the first sub-photodetector and the second sub-photodetector.

According to embodiments, one photodetector may include two photodetectors (a first sub-photodetector and a second sub-photodetector) such that a first semiconductor area of one photodetector includes a first sub-semiconductor area and a second sub-semiconductor area doped with the same type. When the surrounding environment is high-illuminance, in order to improve the accuracy of depth and the deterioration of dispersion, pixel data may be generated using only the first pulse signal generated from the first sub-photodetector, and when the surrounding environment is low-illuminance, in order to maximize the output and optimize the long-distance output, pixel data may be generated using pulse signals generated from each of the first sub-photodetector and the second sub-photodetector.

It should be understood that the detailed description and specific examples, while indicating preferred embodiments of the disclosed technology, are given by illustration only, since various changes and modifications may be made based on what is described or illustrated in this document.

### BRIEF DESCRIPTION OF DRAWINGS

FIG. 1 is a block view showing an imaging system based on some implementations of the disclosed technology.

FIG. 2 is an example of a plan view of a pixel array based on some implementations of the disclosed technology.

FIG. 3 is an example of an enlarged plan view of Q1 shown in FIG. 2.

FIG. 4 is an example of a cross-sectional view cut along A-A′ of FIG. 3.

FIG. 5 is an example of an enlarged cross-sectional view of Q2 shown in FIG. 4.

FIG. 6 is an example of a view illustrating a direct ToF (time of flight) of a pixel.

FIG. 7 is an example of a view illustrating an indirect ToF of a pixel.

FIG. 8 is an example of a view showing an imaging system based on some implementations of the disclosed technology.

FIG. 9 is an example of a view showing a mode of a single photon avalanche diode based on some implementations of the disclosed technology.

FIG. 10 is an example of a view showing an imaging system including a first sub-photodetector and a second sub-photodetector based on some implementations of the disclosed technology

FIG. 11 is an example of a view showing an operation of an imaging system when the distance to a target object is short based on some implementations of the disclosed technology.

FIG. 12 is an example of a view showing an operation of an imaging system when the distance to a target object is long based on some implementations of the disclosed technology.

FIG. 13 is an example of a flow chart showing a method of operating an imaging system based on some implementations of the disclosed technology.

FIG. 14 is an example of a flow chart showing a method of operating an imaging system based on some implementations of the disclosed technology.

FIG. 15 is an example of a plan view of a pixel based on some implementations of the disclosed technology.

FIG. 16 is an example of a cross-sectional view cut along B-B′ of FIG. 15.

### DETAILED DESCRIPTION

Description will now be given in detail according to exemplary embodiments disclosed herein, with reference to the accompanying drawings.

For the sake of brief description with reference to the drawings, the same or equivalent components may be provided with the same reference numbers, and description thereof will not be repeated. “And/or” includes any combination of one or more of the associated configurations that can be defined.

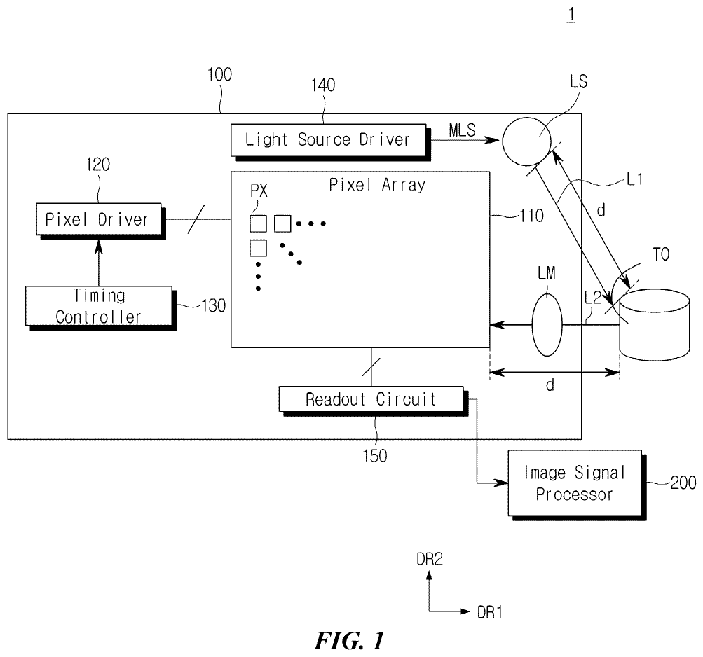

FIG. 1 is a block view showing an imaging system according to one embodiment.

Referring to FIG. 1, the imaging system 1 may refer to a device such as a digital still camera for capturing still images of a target object TO or a digital video camera for capturing moving images of the target object TO. For example, the imaging system 1 may be implemented as a digital single lens reflex (DSLR) camera, a mirrorless camera, or a mobile phone (particularly, a smartphone), but embodiments of the present disclosure are not limited thereto. The imaging system 1 may include a device that can generate an image by including a lens and an imaging element.

The imaging system 1 may include an image sensing device 100 and an image signal processor 200.

The image sensing device 100 may be configured to measure a distance from the target object TO by measuring the time for light to travel to and back from the target object TO using the TOF (time of flight) principle. The image sensing device 100 may include a light collection pattern ML (e.g., a lens) for collecting light from the target object TO, a pixel array 110 of sensing pixels for receiving and sensing the light from the light collection pattern ML, a pixel driver 120 coupled to the pixel array 10, a timing controller 130, a light source driver 140 for controlling a light source LS to generate light to illuminate the target object TO, and a readout circuit 150 coupled to the pixel array 110 for reading out signals from the pixel array 110. The imaging system 1 may operate the light source LS to produce modulated light such as light pulses towards the target object TO for performing the ToF measurement for determining the distance.

The light source LS can irradiate light to the target object TO in response to a clock signal MLS from the light source driver 140. The light source LS can be a combination of a laser diode LD that emits light of a specific wavelength band (e.g., infrared or visible light), a light emitting diode LED, a near infrared laser NIR, a point light source, a monochromatic illumination source combining a white lamp and a monochromator, or another laser light source LS. For example, the light source LS may be configured emit infrared rays having a wavelength of 800 nm to 1000 nm. In FIG. 1, only one light source LS is illustrated for convenience of explanation, but a plurality of light sources LS may be arranged around the light collection pattern ML. For example, the light source LS is exemplified as a near-infrared laser light source (VCSEL Vertical cavity surface emitting laser) including a point light source, but the embodiments are not limited thereto.

The light collection pattern ML can collect light reflected from the target object TO and focus it onto pixels of the pixel array 110. The light collection pattern ML may include a focusing lens or other optical element on a glass or plastic surface. The light collection pattern ML may include a lens group formed by at least one lens. The light collection pattern ML may be a micro lens, but the embodiments are not limited thereto.

The pixel array 110 may include a plurality of pixels SP that are sequentially arranged in a two-dimensional matrix structure including columns and rows. For example, the pixel array 110 may include a plurality of pixels SP that are sequentially arranged along the first direction DR1 and the second direction DR2. Each pixel SP may convert the second light L2 (or incident light) received through the light collection pattern ML into an electrical signal, which may be a pixel signal corresponding to the second light L2, and output the converted signal. At this time, the pixel signal may be a signal representing information corresponding to a distance to the target object TO, rather than a signal representing a color of the target object TO. Each of the plurality of pixels SP may include a photodetector, and the photodetector may include, for example, a single photon avalanche diode SPAD in certain implementations.

The pixel array 110 in which the plurality of pixels SP are arranged can detect a distance to a target object TO using a direct ToF method. For reference, the direct ToF method is a method in which a distance to a target object TO is calculated by directly measuring a round trip time from a time point when pulse light is irradiated to the target object TO to a time point when the pulse light is reflected from the target object TO and is incident on the pixel array 110, and calculating the round trip time and the speed of light. For example, the imaging system may measure time spent in generating the pixel signals since light is emitted from the light source. The light emitted from the light source LS is reflected from the target object TO and arrives at the photodetectors of the pixel array 110, and the pixel signals are generated upon the arrival of the light at the photodetectors. However, the embodiments are not limited thereto, and a pixel array 110 in which the plurality of pixels SP are arranged can also detect a distance to a target object TO using an indirect ToF method.

The pixel driver 120 may drive the pixel array 110 under the control of the timing controller 130. For example, the pixel driver 120 can generate a quenching control signal to control a quenching operation that reduces the reverse bias voltage applied to the pixel SP below the breakdown voltage. That is, the pixel driver 120 may control the turn-on/turn-off of the pixel SP under the control of the timing controller 130.

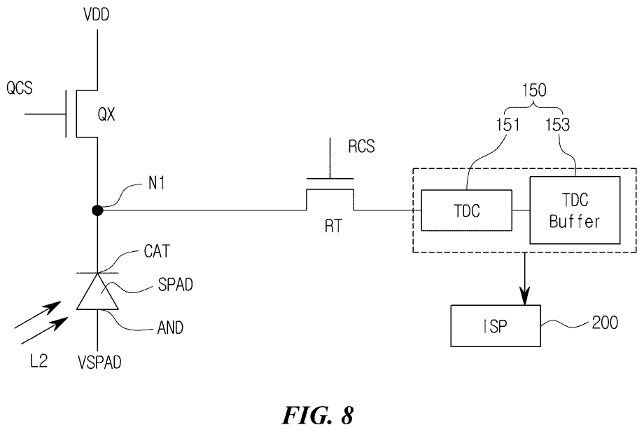

The read-out circuit 150 is arranged on one side of the pixel array 110 and calculates the time delay between the pulse signal (or pixel signal) output from each pixel SP and the reference pulse, and may generate digital data (or pixel data) corresponding to the time delay (see the TDC (time-to-digital) unit 151 of the read-out circuit 150 of FIG. 8) and store (see the TDC buffer (or TDC memory) 153 of the read-out circuit 150 of FIG. 8). The read-out circuit 150 may transmit the stored digital data to the image signal processor 200 under the control of the timing controller 130.

The timing controller 130 may control the overall operation of the image sensing device 100. That is, the timing controller 130 may generate a timing signal for controlling the operation of the pixel driver 120 and the light source driver 140. In addition, the timing controller 130 can control activation or deactivation of the read-out circuit 150 and control digital data stored in each of the read-out circuits 150 to be transmitted simultaneously or sequentially to the image signal processor 200.

The light source driver 140 may be configured to generate a clock signal that can drive the light source LS based on the control of the timing controller 130.

The image signal processor 200 (or ISP) may be configured to process digital data (or pixel data) input from the image sensing device 100 and generate a depth image (in the form of a histogram) indicating the distance to the target object TO. Specifically, the image signal processor 200 may calculate the distance to the target object TO for each pixel based on the time delay indicated by the digital data received from the readout circuit 150.

The image signal processor 200 may be configured to control the operation of the image sensing device 100. In particular, the image signal processor 200 may analyze digital data input from the image sensing device 100 to determine the mode of the image sensing device 100 and control the image sensing device 100 to operate in the determined mode.

The image signal processor 200 may be configured perform image signal processing for noise removal and image quality improvement on the generated depth image. The depth image output from the image signal processor 200 may be stored in the internal memory or external memory of the imaging system 1 or the device equipped with the imaging system 1 based on a user's request or automatically, or may be displayed through a display. In some implementations, the depth image output from the image signal processor 200 may be used to control the operation of the imaging system 1 or the device equipped with the imaging system 1.

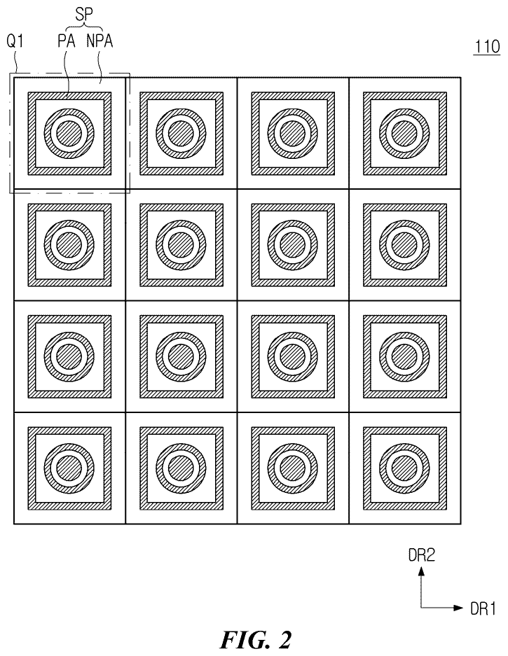

FIG. 2 is shows a plan view of an example of a pixel array according to one embodiment.

Referring to FIG. 2, the pixel array 110 may include a plurality of pixels SP. The plurality of pixels SP may be arranged along the first direction DR1 and the second direction DR2, but the arrangement method of the pixels SP is not limited thereto.

A pixel SP may include a pixel area PA, which reacts to light to produce photocharge for imaging sensing, and a non-pixel area NPA, which does not react to light to produce photocharge and is structured to surround the pixel area PA. The pixel area PA may be an area where a first semiconductor area, a second semiconductor area, and an intermediate area are arranged to effectuate the photosensing. The non-pixel area NPA may be located at a boundary between adjacent pixels SP.

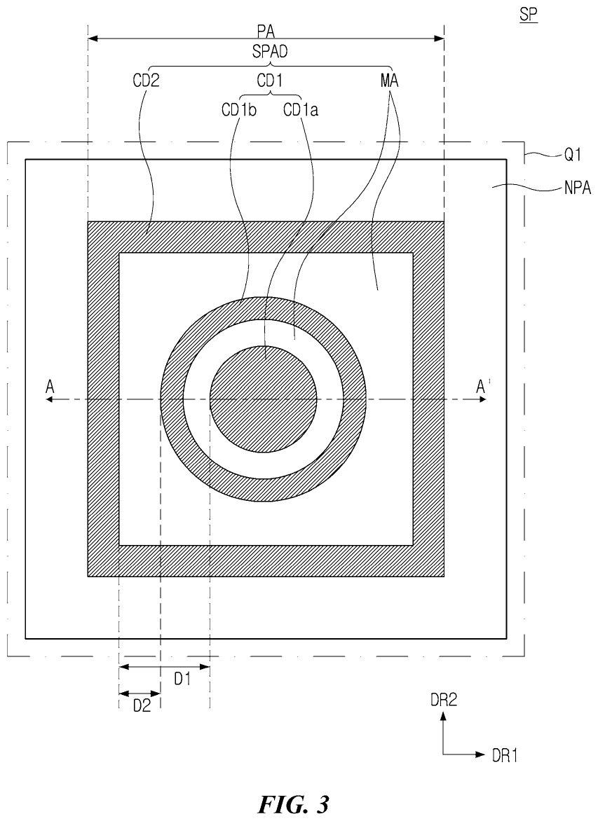

An example of a plan view of one pixel SP is described in FIG. 3.

FIG. 3 is an enlarged plane view of Q1 shown in FIG. 2.

Referring to FIG. 3, a pixel SP may include a pixel area PA and a non-pixel area NPA, and a photodetector (e.g., a SPAD) may be arranged in the pixel area PA. The photodetector SPAD may include a first semiconductor area CD1, a second semiconductor area CD2, and an intermediate area MA. The second semiconductor area CD2 may be disposed outside of the first semiconductor area CD1 and the intermediate area MA and surround the first semiconductor area CD1 and intermediate area MA. The first semiconductor area CD1 may include a first sub-semiconductor area CD1a located in the center, and a second sub-semiconductor area CD1b between the first sub-semiconductor area CD1a and the second semiconductor area CD2. Some of the intermediate area MA may be arranged between the first semiconductor area CD1 and the second semiconductor area CD2, and some of the intermediate area MA may be arranged between the first sub-semiconductor area CD1a and the second sub-semiconductor area CD1b. For example, the intermediate area MA can be positioned between the second sub-semiconductor area CD1b and the second semiconductor area CD2, and between the first sub-semiconductor area CD1a and the second sub-semiconductor area CD1b.

In some implementations, the intermediate area MA may completely surround the first sub-semiconductor area CD1a, and thus, the first sub-semiconductor area CD1a and the second sub-semiconductor area CD1b may be spaced apart from each other by having some of the intermediate area MA between the first sub-semiconductor area CD1a and the second sub-semiconductor area CD. In FIG. 3, the planar shape of the first sub-semiconductor area CD1a is exemplified as being circular, but the embodiments are not limited thereto, and the planar shape of the first sub-semiconductor area CD1a may be square, triangular, oval, or cross-shaped, etc.

In some implementations, the second sub-semiconductor area CD1b may completely surround the first sub-semiconductor area CD1a and some of the intermediate area MA surrounding the first sub-semiconductor area CD1a.

The first sub-semiconductor area CD1a and the second sub-semiconductor area CD1b may be doped with the same conductivity type.

The second semiconductor area CD2 may completely surround the first semiconductor area CD1. The second semiconductor area CD2 may be doped with a different conductivity type from the first semiconductor area CD1. The second semiconductor area CD2 and the second sub-semiconductor area CD1b may be separated by some of the intermediate area MA.

In one embodiment, the separation distance D1 between the first sub-semiconductor area CD1a and the second semiconductor area CD2 may be greater than the separation distance D2 between the second sub-semiconductor area CD1b and the second semiconductor area CD2.

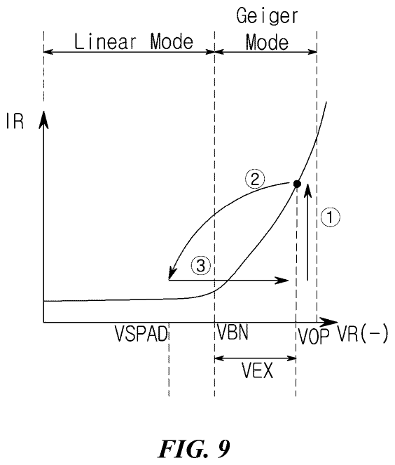

For example, the planar area of the first sub-semiconductor area CD1a may be smaller than the planar area of the second sub-semiconductor area CD1b. As described below, when the distance to the target object is relatively close (e.g., the case that the distance to the target object is less than the predetermined distance), the first pulse signal PS1 is generated using only the first sub-photodetector (see SPAD1 of FIG. 9), and since the planar area of the first sub-semiconductor area CD1a is smaller than the planar area of the second sub-semiconductor area CD1b, there is an advantage in that the accuracy of the depth at a close distance may be further increased. However, the embodiments are not limited thereto, and the planar area of the first sub-semiconductor area CD1a may be the same as the planar area of the second sub-semiconductor area CD1b, or the planar area of the first sub-semiconductor area CD1a may be larger than the planar area of the second sub-semiconductor area CD1b.

Below, an example of the cross-sectional structure of the pixel SP is described.

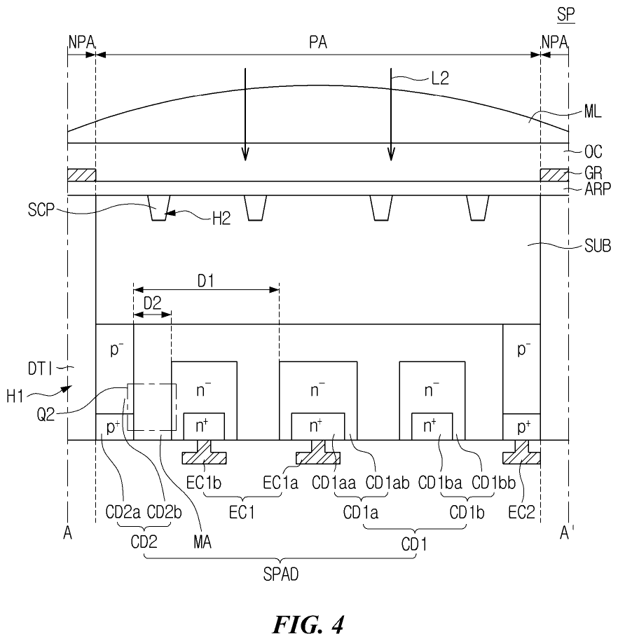

FIG. 4 is an example of a cross-sectional view cut along A-A′ of FIG. 3.

Referring to FIGS. 3 and 4, the pixel SP according to one embodiment may include a circuit portion including first and second electrode portions EC1 and EC2, a substrate SUB including a photodetector SPAD arranged in a pixel area PA on the circuit portion. The pixel SP further includes a portion of the substrate SUB (hereinafter, “a substrate portion SUB”) disposed on the photodetector SPAD, a grid portion GR on the substrate portion SUB, a planarization layer OC disposed on the grid portion GR, and a light collection pattern ML disposed on the planarization layer OC. The photodetector SPAD may be a single-photon avalanche diode, and the light collection pattern ML may be a micro lens, but the embodiments are not limited thereto.

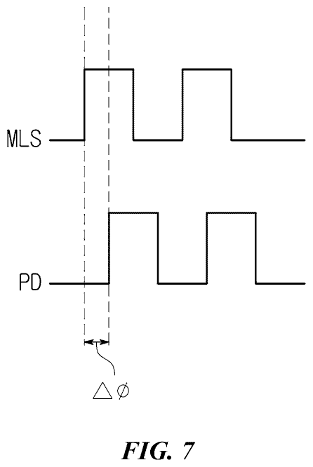

The circuit portion is arranged on the lower surface of the photodetector SPAD and may include transistors, a wiring layer, and an interlayer insulating layer. The transistors may include an analog quenching transistor, a read-out transistor, etc. formed on the lower surface of the photodetector SPAD For example, FIG. 4 shows an example in which the circuit portion includes a first electrode portion EC1 electrically connected to a first semiconductor area CD1, and a second electrode portion EC2 electrically connected to a second semiconductor area CD2. For example, the first electrode portion EC1 may include a first sub-electrode portion EC1a and a second sub-electrode portion EC1b, and the first sub-electrode portion EC1a may be connected to the first sub-semiconductor area CD1a, and the second sub-electrode portion EC1b may be connected to the second sub-semiconductor area CD1b. The second sub-electrode portion EC2 may be connected to the second semiconductor area CD2. The first electrode portion EC1 may be an electrode portion connected to an analog quenching transistor to be described later or an electrode of an analog quenching transistor, and the second electrode portion EC2 may be an electrode portion to which a diode voltage (see VSPAD of FIG. 7) to be described later is applied, but the embodiments are not limited thereto.

The photodetector SPAD may be arranged on the circuit portion. The photodetector SPAD may include the first semiconductor area CD1, the second semiconductor area CD2, and the intermediate area MA. The first sub-semiconductor area CD1a may be arranged between adjacent second sub-semiconductor areas CD1b.

The first semiconductor area CD1 may be an n-type semiconductor area, and the second semiconductor area CD2 may be a p-type semiconductor area. For example, the p-type ions may include boron (B) ions, and the n-type ions may include phosphorous P and/or arsenic As ions. Each of the first sub-semiconductor area CD1a and the second sub-semiconductor areas CD1b, which are included in the first semiconductor area CD1, may include at least two areas having different doping concentrations. For example, the first sub-semiconductor area CD1a may include a 1-1 semiconductor area CD1aa which is an n+-type semiconductor area on the circuit portion, and a 1-2 semiconductor area CD1ab which is an n-type semiconductor area and disposed on the 1-1 semiconductor area CD1aa. Similarly, the second sub-semiconductor area CD1b may include a 1-1 semiconductor area CD1ba which is an n+-type semiconductor area on the circuit portion, and a 1-2 semiconductor area CD1bb which is an n-type semiconductor area and disposed on the 1-1 semiconductor area CD1ba. In the implementations, the second semiconductor area CD2 may include a 2-1 semiconductor area CD2a which is a p+-type semiconductor area and disposed on the circuit portion, and a 2-2 semiconductor area CD2b which is a p-type semiconductor area and disposed on the 2-1 semiconductor area CD2a.

For example, the 1-1 semiconductor area CD1aa and CD1ba may have a higher n-type impurity doping concentration than the 1-2 semiconductor area CD1ab and CD1bb, and the 2-1 semiconductor area CD2a may have a higher p-type impurity doping concentration than the 2-2 semiconductor area CD2b, but the embodiments are not limited thereto, and the 1st semiconductor area CD1 and the 2nd semiconductor area CD2 may include only one n-type, p-type semiconductor area or, conversely, may have more diverse doping concentrations.

In some embodiments, the upper and lower positions of the first-first semiconductor area CD1aa and CD1ba and the 1-2 semiconductor area CD1ab and CD1bb may be changed, and the upper and lower positions of the second-first semiconductor area CD2a and the second-second semiconductor area CD2b may be changed.

The intermediate area MA may be arranged between the first semiconductor area CD1 and the second semiconductor area CD2. The intermediate area MA may also be arranged on the upper surface of the first semiconductor area CD1. The mechanism of electrons (e−) and holes (h+) in the intermediate area MA will be described later.

In FIG. 4, the first semiconductor area CD1 is positioned in the center and the second semiconductor area CD2 is positioned at the periphery, but the embodiments not limited thereto, and the positions of the first and second semiconductor areas (CD1 and CD2) may be changed.

The substrate portion SUB may be placed on the photodetector SPAD. The substrate portion SUB may include an n-type semiconductor area or a p-type semiconductor area. However, the impurity doping concentration of the substrate portion SUB may be lower than that of the first semiconductor area CD1 and the second semiconductor area CD2, respectively.

A first groove H1 may be formed in the non-pixel area NPA of the substrate portion SUB. The first groove H1 may be formed by recessing the substrate portion SUB in the thickness direction, respectively. For example, the first groove H1 may completely recess the bottom surface from the upper surface of the substrate portion SUB in the thickness direction. The first groove H1 may be formed through a deep trench process. A separation portion DTI may be arranged in the first groove H1. The separation portion DTI may be arranged with an insulating material or a conductive material such as poly silicon.

In some embodiments, a second groove H2 may be formed in the pixel area PA. The second groove H2 may be provided in one, two, or three or more. The thickness (or depth) of the second groove H2 may be smaller than the thickness (or depth) of the first groove H1. A scattering pattern SCP may be arranged in the second groove H2. The scattering pattern SCP may include at least one of the materials constituting the anti-reflection layer ARP to be described later, but the embodiments are not limited thereto.

An anti-reflection layer ARP may be arranged on the substrate portion SUB. The anti-reflection layer ARP may serve to allow second light L2 incident from the outside to be incident into the substrate SUB without being reflected. The anti-reflection layer ARP may include an insulating material. Examples of the insulating material may include HfO2, SiO2, or Al2O3, but the embodiments are not limited thereto.

The grid portion GR may be arranged on the anti-reflection layer ARP. The grid portion GR may include a metal that blocks the second light L2 incident from the outside, but the embodiments are not limited thereto. The grid portion GR may include tungsten (W), but the embodiments are not limited thereto. The grid portion GR may be arranged in a non-pixel area NPA.

The planarization layer OC may be arranged on the grid portion GR and the anti-reflection layer ARP. The planarization layer OC may include an organic material, but the embodiments are not limited thereto and may include an inorganic material.

The light collection pattern ML may be arranged on the planarization layer OC. The light collection pattern ML may collect light incident from the outside and direct it to the first pixel area PA1. In some implementation, the light collection pattern ML may have a shape of a convex lens convex upward, and may be formed of a material having a large difference in refractive index compared to the outside air (Air). For example, the refractive index of the light collection pattern ML may be about 1.5 to about 1.6, but the embodiments are not limited thereto.

The SPAD may be used as a photoelectric conversion element including a photosensitive P-N junction. Thus, the SPAD can detect a single photon (a single photon of L2) reflected by a target object (see TO in FIG. 1) and generate pixel data (or a current pulse, a pixel signal, a pulse signal) corresponding to the detected single photon. At this time, the pixel data may be generated through a series of processes in which avalanche breakdown is triggered by an incident single photon in a Geiger mode in which a reverse bias voltage higher than a breakdown voltage is applied between the cathode and the anode.

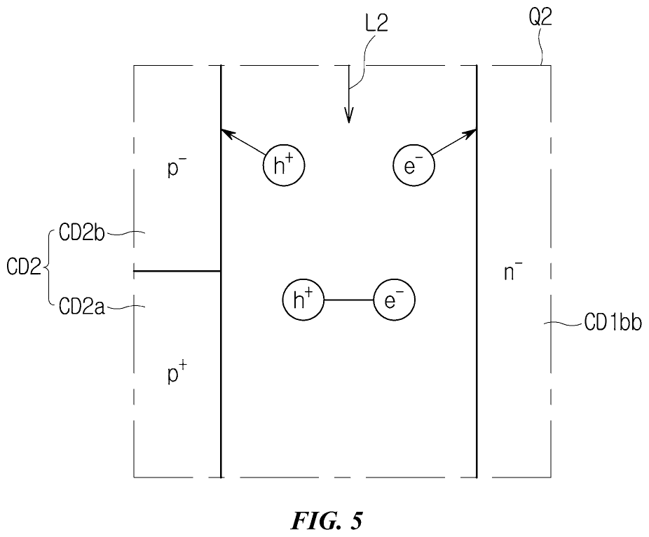

FIG. 5 is an enlarged cross-sectional view of Q2 shown in FIG. 4.

Referring to FIG. 5, avalanche breakdown may occur in the intermediate area MA within the photodetector SPAD. Holes (h+) may be arranged in one area adjacent to the second semiconductor area CD2 of the intermediate area MA, and electrons (e−) may be arranged in the other area adjacent to the 1-2 semiconductor area CD1bb of the intermediate area MA. The holes (h+) of one area and the electrons (e−) of the other area may be combined to form an electron (e−)-hole (h+) pair. The electron (e−)-hole (h+) pair can undergo impact ionization by a photon of the second light L2. The intermediate area MA includes semiconductor materials such as Si.

Specifically, when a reverse bias voltage is applied to the photodetector SPAD to increase the electric field, impact ionization occurs, in which electrons (e−) generated by incident photons move and create electron-hole (h+) pairs. When the electrons (e−) and holes (h+) generated by the impact ionization phenomenon collide with each other, countless carriers can be generated.

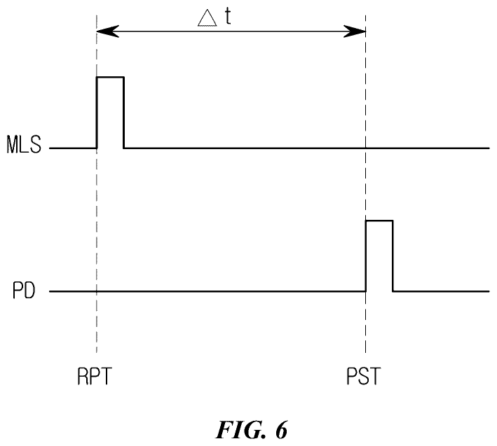

FIG. 6 is a view to describe the direct ToF of a pixel.

Referring to FIG. 1 and FIG. 6, when the image sensing device 100 is activated, the light source LS can irradiate the first light L1 (or irradiated light) to the target object TO by the reference pulse signal MLS. The point in time at which the pulse of the reference pulse signal MLS is generated can be defined as the reference pulse time point RPT. The pixel array 110 and the read-out circuit 150 can detect the pulse signal reflected from the target object TO and incident thereon to generate pixel data PD.

The image signal processor ISP 200 may process pixel data PD input from the image sensing device 100 and generate a depth image (in the form of a histogram) indicating the distance to the target object TO. When the direct ToF method is applied, the image signal processor 200 can calculate the distance to the target object TO for each pixel based on the time delay indicated by the pixel data PD received from the readout circuit 150. The image signal processor 200 can analyze the pixel data PD and determine the point in time when the pixel data PD has a value greater than or equal to a threshold data as the pulse detection point PST. The image signal processor 200 calculates the time of flight To and Δt, which is the time difference from the reference pulse time point RPT to the pulse detection time point PST, and calculates the distance between the target object TO and the image sensing device 100 by calculating the calculated time of flight (Δt) and the speed of light (e.g., multiplying the value of Δt divided by 2 by the speed of light).

FIG. 7 is a view to describe the indirect ToF of a pixel.

Referring to FIG. 1 and FIG. 7, when the image sensing device 100 is activated, the light source LS can irradiate the first light L1 (or irradiated light) to the target object TO by the reference pulse signal MLS. The point in time at which the pulse of the reference pulse signal MLS is generated can be defined as the reference pulse time point RPT. The pixel array 110 and the read-out circuit 150 can detect the pulse signal reflected from the target object TO and incident thereon to generate pixel data PD.

The image signal processor 200 may process pixel data PD input from the image sensing device 100 and generate a depth image (in the form of a histogram) indicating the distance to the target object TO. When the indirect ToF method is applied, the image signal processor 200 may calculate the distance to the target object TO for each pixel based on the phase delay (Δa) indicated by the pixel data PD received from the readout circuit 150.

The imaging system according to one embodiment may operate in a direct ToF manner, but the embodiments are not limited thereto. For convenience of explanation, the following description will focus on the direct ToF manner.

FIG. 8 is a view showing an imaging system according to one embodiment.

Referring to FIG. 8, the imaging system according to one embodiment may include a photodetector SPAD, an analog quenching transistor QX, a read-out transistor RT, a read-out circuit 150, and an ISP 200. An anode electrode AND may be formed at one end of the photodetector SPAD, and a cathode electrode CAT may be formed at the other end. The anode electrode AND and the cathode electrode CAT are relative concepts to each other, and their positions may be exchanged. For example, the anode electrode AND may be a second semiconductor area CD2 of the photodetector SPAD, and the cathode electrode CAT may be a first semiconductor area CD1 of the photodetector SPAD, but the embodiments are not limited thereto. A diode voltage VSPAD may be applied to the anode electrode AND of the photodetector SPAD. A cathode electrode CAT can be connected to a first node N1. A second light L2 is applied to a photodetector SPAD (see FIG. 3). An analog quenching transistor QX is connected to the first node N1). An analog quenching voltage VDD is applied to a first electrode of the analog quenching transistor QX, a second electrode is connected to the first node N1, a quenching control signal QCS is applied to a gate electrode, and turn-on/turn-off of the analog quenching transistor QX may be controlled by the quenching control signal QCS.

A read-out transistor RT may be connected to the first node N1 A first electrode of the read-out transistor RT is connected to the first node N1, a second electrode is connected to the read-out circuit 150, the read-out control signal RCS is applied to a gate electrode, and turn-on/turn-off of the read-out transistor RT can be controlled by the read-out control signal RCS.

FIG. 9 is a view showing a mode of a single photon avalanche diode according to one embodiment. The horizontal axis of FIG. 9 represents the voltage VR applied to a single-photon avalanche diode (see SPAD in FIG. 8), and the vertical axis represents the current IR output from the single-photon avalanche diode (see SPAD in FIG. 7).

Referring to FIGS. 8 and 9, the mode of the single photon avalanche diode may include a linear mode and a Geiger mode. The linear mode and the Geiger mode are distinguished based on the breakdown voltage VBV. If the voltage applied to the photodetector (hereinafter referred to as a SPAD) is higher than the breakdown voltage VBV, the photodetector SPAD operates in the Geiger mode, and if the voltage applied to the photodetector SPAD is less than the breakdown voltage VBV, the photodetector SPAD may operate in the linear mode. The voltage VR applied to the photodetector SPAD may be based on the (−) voltage. Therefore, in this specification, it is considered that the larger the (−) value, the larger the voltage size. However, the embodiments are not limited thereto. In the linear mode and the Geiger mode, the diode voltage VSPAD may have a constant size. For example, the diode voltage VSPAD may be set to have a voltage lower than the breakdown voltage VBV. When the diode voltage VSPAD is lower than the breakdown voltage VBV, the photodetector SPAD may enter the Geiger mode even though the analog quenching transistor QX is not turned on. In this case, even though the light L2 is not applied, avalanche may occur randomly and a large current IR may be generated from the photodetector SPAD. Therefore, it is preferable that the diode voltage VSPAD be set to have a voltage lower than the breakdown voltage VBV.

For a more detailed explanation of the Geiger mode and the linear mode, each voltage magnitude will be explained with an example. The breakdown voltage VBV can be −20 V, and the diode voltage VSPAD can be −19 V. When the analog quenching transistor QX is turned off, the voltage applied to the photodetector SPAD is −19 V, which is smaller than the breakdown voltage VBV, so the photodetector SPAD operates in the linear mode. In the linear mode, even if light L2 is incident on the photodetector SPAD, the size of the current IR output from the photodetector SPAD is not large, and the size of the current IR increases in proportion to the number of carriers (e− or h+) generated by impact ionization, but the number of carriers may not be large. Even when the analog quenching transistor QX is turned on, if the analog quenching voltage VDD is less than 1 V, the voltage VR across the photodetector SPAD is −19 V—(a voltage less than 1 V), which is less than the breakdown voltage VBV, so the photodetector SPAD operates in linear mode.

### Reset Operation

In the reset operation \textcircled{3}, when an analog quenching voltage VDD of 1 V is applied, the voltage VR applied to the photodetector SPAD becomes equal to the breakdown voltage VBV. From this time, the photodetector SPAD operates in Geiger mode. In the Geiger mode, as the voltage VR applied to the photodetector SPAD increases, the size of the current IR output from the photodetector SPAD increases very steeply. However, in the reset operation \textcircled{3}, when the voltage VR applied to the photodetector SPAD is set equal to the breakdown voltage VBV, the photodetector SPAD may operate in linear mode instead of Geiger mode due to some error. Therefore, in the reset operation \textcircled{3}, the voltage VR applied to the photodetector SPAD may be set to the operating voltage VOP. For example, the operating voltage VOP may be greater than the breakdown voltage VBV, and for example, let's assume it to be −23 V. That is, the reset operation \textcircled{3} performs an operation of presetting the operating voltage VOP greater than the breakdown voltage VBV and increasing the voltage VR applied to the photodetector SPAD to the operating voltage VOP through the analog quenching voltage VDD. In order to increase the voltage VR applied to the photodetector SPAD to −23 V, which is the operating voltage VOP, the analog quenching voltage VDD must be 4 V (−19 V-4 V=−23 V). The voltage obtained by subtracting the breakdown voltage VBV from the operating voltage VOP can be the set voltage VEX, and in this case, it can be −2 V.

### Avalanche Operation

In the avalanche operation \textcircled{1}, since the photodetector SPAD experiences a lot of collision ionization and generates a large number of carriers, the magnitude of the current IR output from the photodetector SPAD may be high. That is, since the magnitude of the output current IR is high, the operation of generating a pulse signal reflected and incident from the target object TO described in FIG. 4 may be performed in the avalanche operation \textcircled{1} of the photodetector SPAD. The pulse signal generated from the photodetector SPAD is provided to the read-out circuit 150 when the read-out transistor RT is turned on. The TDC 151 of the read-out circuit 150 generates pixel data PD based on the pulse signal generated and transmitted from the photodetector SPAD, and the TDC buffer 153 stores the generated pixel data PD.

### Quenching Operation

In the quenching operation \textcircled{2}, the analog quenching transistor QX is turned off, and thus, the voltage VR applied to the photodetector SPAD may be lowered to the diode voltage VSPAD level again. The photodetector SPAD according to one embodiment repeats the reset operation \textcircled{3}, the avalanche operation \textcircled{1}, and the quenching operation \textcircled{2}.

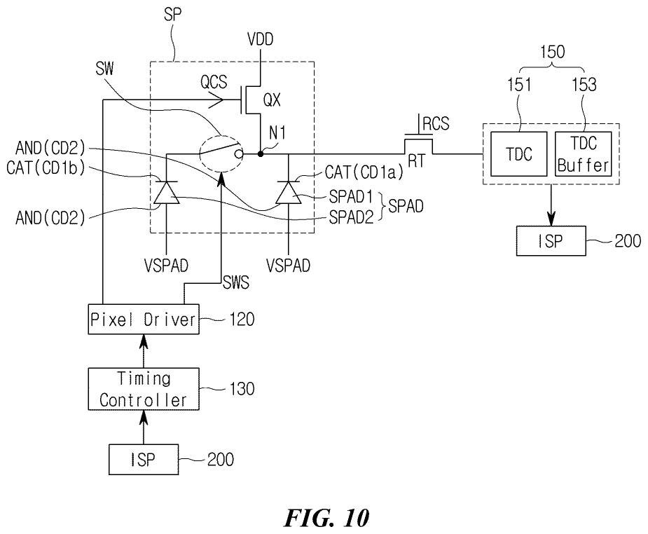

FIG. 10 is a view showing an imaging system including a first sub-photodetector and a second sub-photodetector according to one embodiment.

Referring to FIG. 10, the imaging system 1 according to one embodiment may include a pixel SP. A pixel driver 120 may control turning on or off of an analog quenching transistor QX of the pixel SP by applying a quenching control signal QCS to a gate electrode of the analog quenching transistor QX of the pixel SP. The pixel SP may include multiple photodetectors which include a first sub-photodetector SPAD1 and a second sub-photodetector SPAD2. Thus, according to one embodiment, one pixel SP may have two photodetectors SPAD1 and SPAD2. In the example, each of the first sub-photodetector SPAD1 and a second sub-photodetector SPAD2 may have a structure same as the photodetector SPAD as shown in FIGS. 3 and 4.

The anode electrode AND of the first sub-photodetector SPAD1 may be connected to the second semiconductor area CD2, and the cathode electrode CAT may be connected to the first sub-semiconductor area CD1a. The anode electrode AND of the second sub-photodetector SPAD2 may be connected to the second semiconductor area CD2, and the cathode electrode CAT may be connected to the second sub-semiconductor area CD1b. The anode electrode AND of the first sub-photodetector SPAD1 may be connected to the first node N1.

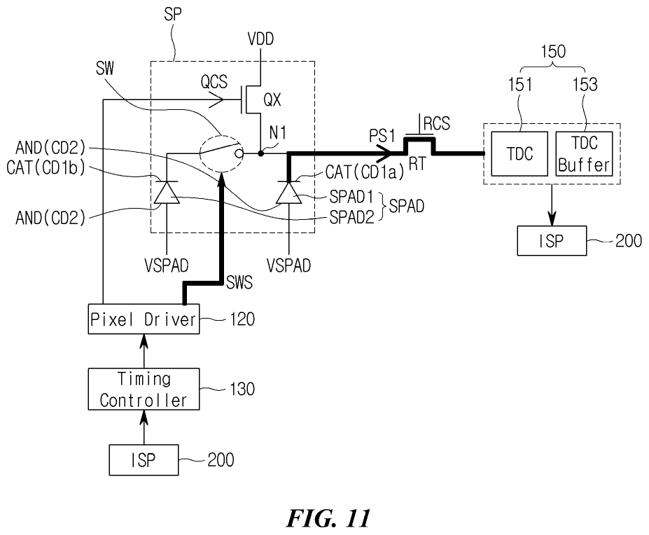

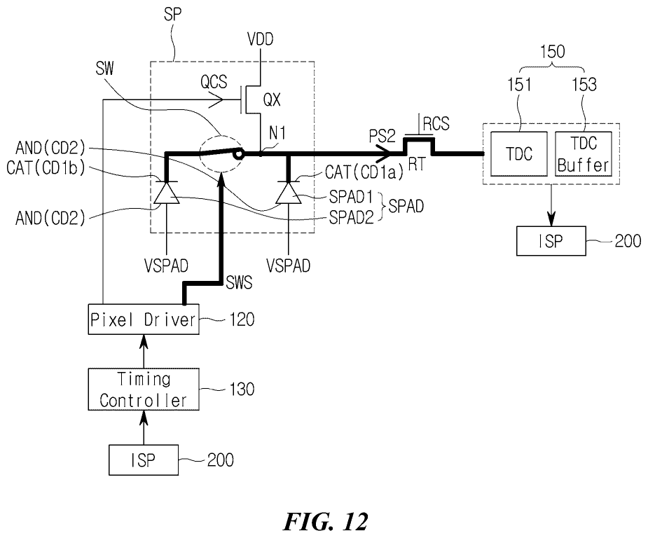

According to one embodiment, a pixel SP may further include a switch SW disposed between a first node N1 and a second sub-photodetector SPAD2. The switch SW may be disposed between the first sub-photodetector SPAD1 and the second sub-photodetector SPAD2. The switch SW may be turned on or off by a switch control signal SWS. The switch control signal SWS may be output from the pixel driver 120. The operation of the switch SW will be described with reference to FIGS. 11 and 12.

FIG. 11 is a view showing an operation of an imaging system when the distance to a target object is close.

Referring to FIG. 11, the imaging system according to one embodiment may measure a distance to a target object. For example, the distance to the target object may be measured using both the first sub-photodetector SPAD1 and the second sub-photodetector SPAD2, or the distance to the target object may be measured using only the first sub-photodetector SPAD1. After measuring the distance to the target object, it can be determined whether the distance to the target object is greater than a reference distance (i.e., the distance to the target object is determined as long distance) or less than the reference distance (i.e., the distance to the target object is determined as short distance). The reference distance may be predetermined and stored in the imaging system. FIG. 11 describes the operation of the imaging system when the distance to the target object is determined as short distance. When the distance to the target object is short distance, the timing controller 130 may output a switch control signal SWS of a turn-off signal from the pixel driver 120 according to the control of the ISP 200. The switch SW is turned off by the switch control signal SW2 of the turn-off signal, and the second sub-photodetector SPAD2 may not be connected to the first node N1, the analog quenching transistor QX, and the first sub-photodetector SPAD1.

The first sub-photodetector SPAD1 of the pixel SP generates a first pulse signal PS1 and transmits it to the read-out transistor RT, and the read-out transistor RT may be turned on/off controlled by a read-out control signal RCS. The first pulse signal PS1 is transmitted to the read-out circuit 150 through the read-out transistor RT. The TDC 151 of the read-out circuit 150 receives the first pulse signal PS1 and generates first pixel data PD1. The TDC buffer 153 stores the first pixel data PD1 received from the TDC 151 and transmits it to the ISP 200.

According to the imaging system according to one embodiment, when the distance to the target object is close, the first pulse signal PS1 is generated using only the first sub-photodetector SPAD1 among the photodetectors SPADs, thereby increasing the accuracy of the depth and improving the deterioration of the dispersion. In addition, as described above in FIG. 3, the distance D1 between the first sub-semiconductor area CD1a and the second semiconductor area CD2 is greater than the distance D2 between the second sub-semiconductor area CD1b and the second semiconductor area CD2, so that the first pulse signal PS1 output from the first sub-photodetector SPAD1 itself may be smaller than the pulse signal output from the second sub-photodetector SPAD2 itself. Therefore, there is an advantage in that the accuracy of the depth at a close distance can be further increased.

FIG. 12 is a view showing an operation of an imaging system when the distance to a target object is long.

Referring to FIG. 12, it is determined whether the distance to the target object is greater than or equal to a reference distance (long distance) or less than or equal to a reference distance (short distance). In some implementations, the determination can be made after measuring the distance to the target objection or before measuring the distance to the target object. FIG. 12 describes the operation of the imaging system when the distance to the target object is long distance. When the distance to the target object is long distance, the timing controller 130 may output a switch control signal SWS of a turn-on signal from the pixel driver 120 according to the control of the ISP 200. The switch SW is turned on by the switch control signal SW2 of the turn-on signal, and the second sub-photodetector SPAD2 may be connected to the first node N1, the analog quenching transistor QX, and the first sub-photodetector SPAD1.

The first sub-photodetector SPAD1 and the second sub-photodetector SPAD2 of the pixel SP generate a second pulse signal PS2 and transmit it to the read-out transistor RT, and the read-out transistor RT may be turned on/off controlled by a read-out control signal RCS. The second pulse signal PS2 is transmitted to the read-out circuit 150 through the read-out transistor RT. The TDC 151 of the read-out circuit 150 receives the second pulse signal PS2 and generates second pixel data PD2. The TDC buffer 153 stores the second pixel data PD2 received from the TDC 151 and transmits it to the ISP 200.

According to the imaging system according to one embodiment, when the distance to the target object is long, the first sub-photodetector SPAD1 and the second sub-photodetector SPAD2 are both used to generate a second pulse signal PS2 greater than the first pulse signal PS1, thereby maximizing the pulse signal output at a long distance.

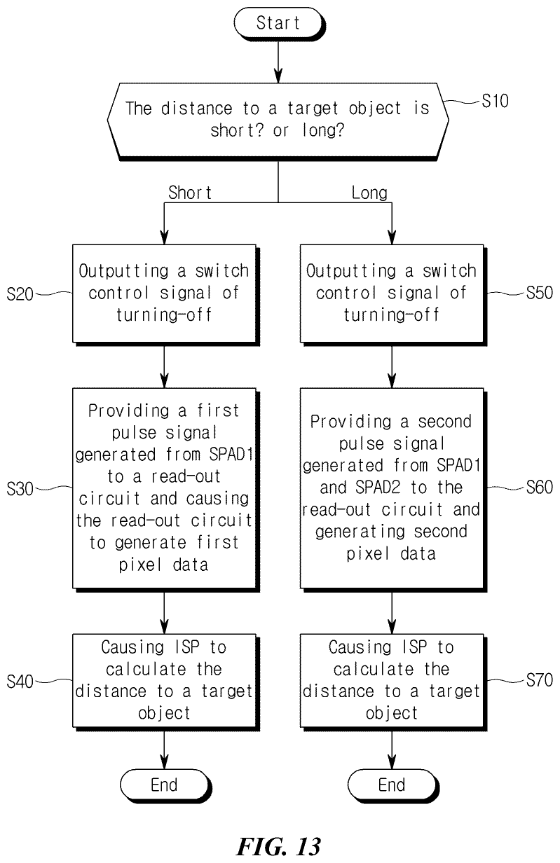

FIG. 13 is a flow chart showing a method of operating an imaging system according to one embodiment. When explaining the flow chart of FIG. 13, FIGS. 1 to 12 may be referred to together, and a detailed description of the parts explained in FIGS. 1 to 12 will be omitted.

Referring to FIG. 13, a method of operating an imaging system according to an embodiment may include a step S10 of determining whether a distance to a target object is close (or less than a reference distance) or far (or greater than a reference distance). In the step S10, the distance to the target object may be measured using both the first sub-photodetector (see SPAD1 of FIG. 11) and the second sub-photodetector (see SPAD2 of FIG. 11), but the distance to the target object may also be measured using only the first sub-photodetector SPAD1. After measuring the distance to the target object, it may be determined whether the distance to the target object is greater than a reference distance (far) or less than a reference distance (short). The determination of the step S10 may be performed in the ISP (see 200 of FIG. 11).

Next, the operating method of the imaging system according to one embodiment may include a step S20 of outputting a switch control signal for turning off when the distance to the target object is short. The switch control signal (see SW of FIG. 11) may be output from a pixel driver (see 120 of FIG. 11).

Next, the method of operating the imaging system according to one embodiment may include a step S30 of providing a first pulse signal (see PS1 of FIG. 11) generated from a first sub-photodetector SPAD1 to a read-out circuit (see 150 of FIG. 11) and causing the read-out circuit 150 to generate first pixel data (PD1 of FIG. 11). The TDC (see 151 of FIG. 11) of the read-out circuit 150 receives the first pulse signal PS1 and generates first pixel data PD1.

Next, the method of operating the imaging system according to one embodiment may include a step S40 in which the ISP (see 200 of FIG. 11) calculates a distance to a target object based on the first pixel data PD1.

The method of operating the imaging system according to one embodiment may include a step S50 in which, if the distance to the target object is long, the switch control signal for turning on is output. The switch control signal (see SW of FIG. 12) may be output from the pixel driver (see 120 of FIG. 12).

Next, the method of operating the imaging system according to one embodiment may include a step S60 of providing a second pulse signal (see PS2 of FIG. 12) generated from the first sub-photodetector SPAD1 and the second sub-photodetector SPAD2 to the read-out circuit (see 150 of FIG. 12) and the read-out circuit 150 generates second pixel data (PD2 of FIG. 12). The TDC (see 151 of FIG. 12) of the read-out circuit 150 receives the second pulse signal PS2 and generates second pixel data PD2.

Next, the method of operating the imaging system according to one embodiment may include a step (S70) of calculating a distance to a target object based on the second pixel data PD2 by the ISP (see 200 of FIG. 12).

Hereinafter, an imaging system according to another embodiment and a method of operating the imaging system will be described.

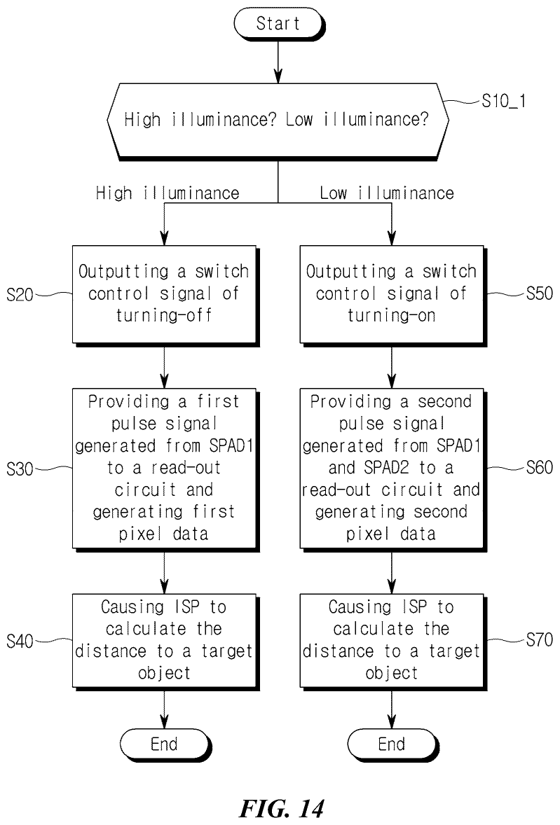

FIG. 14 is a flow chart showing a method of operating an imaging system according to another embodiment.

Unlike the imaging systems of FIGS. 10 and 14, the imaging system of FIG. 14 can control the turn-off/turn-on of the switch based on whether the illumination of the surrounding environment is high illumination (or higher than the reference illumination) or low illumination (or lower than the reference illumination).

Referring to FIG. 14, the method of operating the imaging system according to the present embodiment may include a step (S10_1) of determining whether the illuminance of the surrounding environment is high illuminance (or higher than the reference illuminance) or low illuminance (or lower than the reference illuminance). In the step (S10_1), the illuminance sensor 300 of FIG. 1 may be used. After measuring the illuminance of the surrounding environment through the illuminance sensor 300, the measured illuminance is transmitted to the ISP 200, so that the illuminance of the surrounding environment can be determined.

Next, the method of operating the imaging system according to the present embodiment may include a step (S20) of outputting a switch control signal for turning off when the distance to the target object is short. The switch control signal (see SW of FIG. 11) may be output from a pixel driver (see 120 of FIG. 11).

Next, the method of operating the imaging system according to the present embodiment may include a step (S30) of providing a first pulse signal (see PS1 of FIG. 11) generated from the first sub-photodetector SPAD1 to a read-out circuit (see 150 of FIG. 11) and the read-out circuit 150 generates first pixel data (PD1 of FIG. 11). The TDC (see 151 of FIG. 11) of the read-out circuit 150 receives the first pulse signal PS1 and generates first pixel data PD1.

Next, the method of operating the imaging system according to the present embodiment may include a step S40 of calculating a distance to a target object based on the first pixel data PD1 by the ISP (see 200 of FIG. 11).

The method of the operating imaging system according to the present embodiment may include a step S50 of outputting a switch control signal for turning on when the distance to the target object is long. The switch control signal (see SW of FIG. 12) may be output from a pixel driver (see 120 of FIG. 12).

Next, the method of operating the imaging system according to the present embodiment may include a step S60 of providing a second pulse signal (see PS2 of FIG. 12) generated from the first sub-photodetector SPAD1 and the second sub-photodetector SPAD2 to a read-out circuit (see 150 of FIG. 12) and causing the read-out circuit 150 to generate second pixel data (PD2 of FIG. 12). The TDC (see 151 of FIG. 12) of the read-out circuit 150 receives the second pulse signal PS2 and generates second pixel data PD2.

Next, the method of operating the imaging system according to the present embodiment may include a step S70 in which the ISP (see 200 of FIG. 12) calculates a distance to a target object based on the second pixel data PD2.

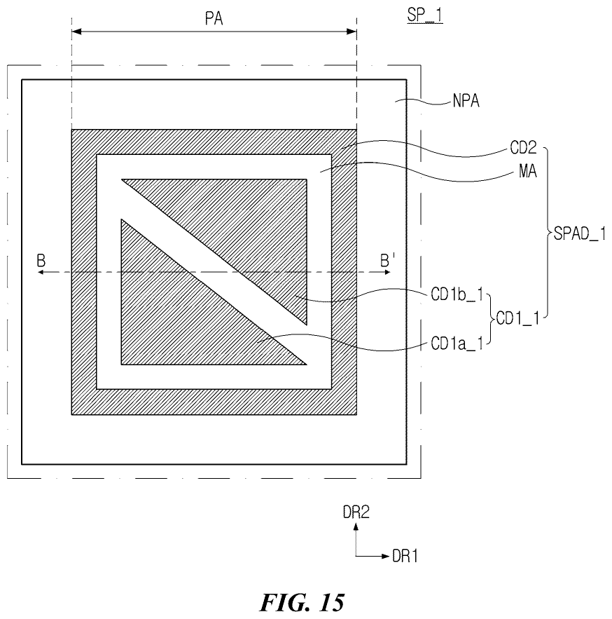

FIG. 15 is a plan view of a pixel according to another embodiment.

Referring to FIG. 15, a pixel SP_1 according to the present embodiment may include a pixel area PA and a non-pixel area NPA, and a photodetector SPAD_1 may be arranged in the pixel area PA. The photodetector SPAD_1 may include a first semiconductor area CD1_1, a second semiconductor area CD2, and an intermediate area MA. The first semiconductor area CD1_1 may include a first sub-semiconductor area CD1a_1, and a second sub-semiconductor area CD1b_1 spaced apart from the first sub-semiconductor area CD1a_1. The intermediate area MA may be arranged between the first semiconductor area CD1_1 and the second semiconductor area CD2. For example, the intermediate area MA can be positioned between the second sub-semiconductor area CD1b_1 and the second semiconductor area CD2, between the first sub-semiconductor area CD1a_1 and the second sub-semiconductor area CD1b_1, and between the first sub-semiconductor area CD1a_1 and the second semiconductor area CD2.

In FIG. 15, the planar shape of the first sub-semiconductor area CD1a_1 and the planar shape of the second sub-semiconductor area CD1b_1 are illustrated as being triangular, but the embodiments are not limited thereto, and the planar shape of the first sub-semiconductor area CD1a_1 and the planar shape of the second sub-semiconductor area CD1b_1 may be square, elliptical, circular, or others.

In the present embodiment, the areas of the first sub-semiconductor area CD1a_1 and the second sub-semiconductor area CD1b_1 are exemplified as being the same, but the embodiments are not limited thereto, and the planar area of the first sub-semiconductor area CD1a_1 may be smaller than the planar area of the second sub-semiconductor area CD1b_1. As described above, when the distance to the target object is a short distance, the first pulse signal PS1 is generated using only the first sub-photodetector (see SPAD1 of FIG. 9), and since the planar area of the first sub-semiconductor area CD1a_1 is smaller than the planar area of the second sub-semiconductor area CD1b_1, there is an advantage in that the accuracy of the depth at a short distance can be further increased. However, the embodiments are not limited thereto, and the planar area of the first sub-semiconductor area CD1a_1 may be larger than the planar area of the second sub-semiconductor area CD1b_1.

Below, the cross-sectional structure of the pixel (SP_1) will be described.

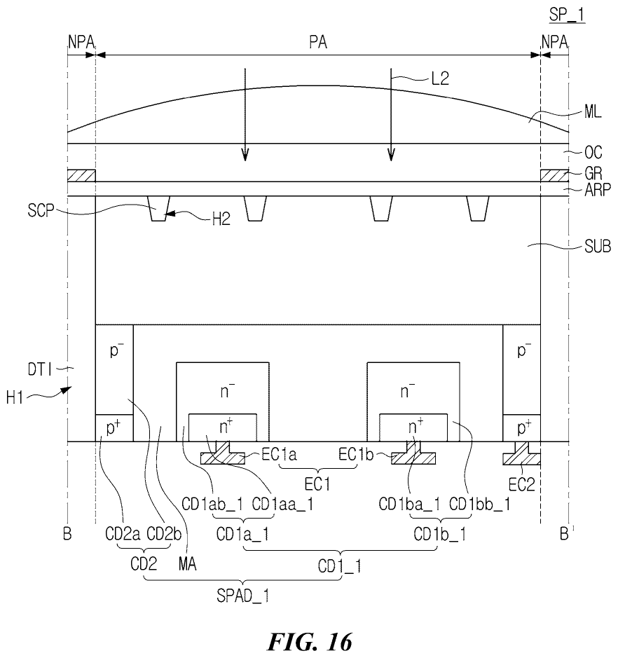

FIG. 16 is a cross-sectional view cut along B-B′ of FIG. 15.

Referring to FIGS. 15 and 16, the pixel SP_1 according to the present embodiment is different from the pixel SP of FIG. 4 in that it includes a photodetector SPAD_1 arranged in a pixel area PA on a circuit portion.

The first sub-electrode portion EC1a may be connected to the first sub-semiconductor area CD1a_1, and the second sub-electrode portion EC1b may be connected to the second sub-semiconductor area CD1b_1.

The photodetector SPAD may include a first semiconductor area CD1_1, a second semiconductor area CD2, and an intermediate area MA.

The first semiconductor area CD1a_1 and CD1b_1 may include the first-first semiconductor area CD1aa_1 and CD1ba_1, which is an n+-type semiconductor area on the circuit portion, and the first-second semiconductor area CD1ab_1 and CD1bb_1, which is an n-type semiconductor area on the first-first semiconductor area CD1aa_1 and CD1ba_1.

As described above in FIG. 10, in the case of the photodetector SPAD_1, the first sub-photodetector SPAD1 and the second sub-photodetector SPAD2 may also be included.

The anode electrode AND of the first sub-photodetector SPAD1 may be connected to the second semiconductor area CD2, and the cathode electrode CAT may be connected to the first sub-semiconductor area CD1a_1. The anode electrode AND of the second sub-photodetector SPAD2 may be connected to the second semiconductor area CD2, and the cathode electrode CAT may be connected to the second sub-semiconductor area CD1b_1. The anode electrode AND of the first sub-photodetector SPAD1 may be connected to the first node N1.

For the imaging system (or pixel SP_1) according to the present embodiment, the operation method described in FIG. 13 or FIG. 14 can be applied.

The method of operating the image sensing device, the imaging system, and the imaging system according to various embodiments of the present disclosure will be described as follows.

In one aspect, an image sensing device is provided to comprise: a substrate; and a photodetector supported by the substrate and structured to comprise a first semiconductor area and a second semiconductor area surrounding the first semiconductor area, wherein the first semiconductor area includes a first sub-semiconductor area and a second sub-semiconductor area spaced apart from the first sub-semiconductor area, and wherein the first sub-semiconductor area and the second sub-semiconductor area are doped with a same conductivity type, and the second semiconductor area is doped with a different conductivity type from the first semiconductor area.

In some implementations, a separation distance between the first sub-semiconductor area and the second semiconductor area is greater than a separation distance between the second sub-semiconductor area and the second semiconductor area.

In some implementations, the photodetector further comprises an intermediate area that is disposed between the first sub-semiconductor area and the second sub-semiconductor area and between the first semiconductor area and the second semiconductor area.

In some implementations, the photodetector further comprises an intermediate area that is disposed between the first sub-semiconductor area and the second sub-semiconductor area, between the second sub-semiconductor area and the second semiconductor area, and between the first semiconductor area and the second semiconductor area.

In some implementations, the photodetector comprises a single photon avalanche diode.

In some implementations, the image sensing device further comprises: an analog quenching transistor connected to the photodetector to turn on or off power to the photodetector, an additional photodetector, and a switch coupled between the photodetector and the additional photodetector to turn or off a connection between the photodetector and the additional photodetector.

In some implementations, the additional photodetector is connected to the analog quenching transistor in response to the switch being turned on, and is not connected to the analog quenching transistor in response to the switch being turned off.

In some implementations, a cathode electrode of the photodetector is connected to the first sub-semiconductor area, and a cathode electrode of the additional photodetector is connected to the second sub-semiconductor area.

In some implementations, the image sensing device further comprises: a read-out transistor connected to the photodetector; and a read-out circuit connected to the read-out transistor.

In some implementations, in response to the switch being turned off, a first pulse signal generated from the photodetector is provided to the read-out circuit through the read-out transistor, and in response to the switch being turned on, the first pulse signal and a second pulse signal generated from the additional photodetector are provided to the read-out circuit through the read-out transistor.

In another aspect, an imaging device is provided to comprise: an image sensing device including a pixel comprising a first photodetector and a second photodetector, and a switch coupled to the first photodetector to turn on or off a connection between the first and second photodetectors, wherein each of the first photodetector and the second photodetector comprises a first semiconductor area and a second semiconductor area surrounding the first semiconductor area, and the first semiconductor area includes a first sub-semiconductor area and a second sub-semiconductor area spaced apart from the first sub-semiconductor area; an image signal processor coupled to the image sensing device to receive pixel data from the pixel of the image sensing device and configured to process pixel data generated from the image sensing device; and a switch controller, wherein the pixel of the image sensing device further comprises an analog quenching transistor connected to the photodetector, and a switch turned on or off by the switch controller and arranged between the first photodetector and the second photodetector.

In some implementations, the switch is turned on or off based on a distance to a target object determined based on the pixel data.

In some implementations, the imaging device further comprises: an illuminance sensor, wherein the switch is turned on or off based on an illuminance of an environment external to the imaging device and determined by the illuminance sensor.

In some implementations, the first sub-semiconductor area and the second sub-semiconductor area are doped with a same conductivity type, and the second semiconductor area is doped with a different conductivity type from the first semiconductor area.

In some implementations, the photodetector comprises a single photon avalanche diode.

In another aspect, a method of operating an imaging device is provided. The method comprises: making a determination whether a distance to a target object is greater than or equal to a predetermined distance; turning off or on a switch disposed between a first sub-photodetector and a second sub-photodetector that are included in the imaging device based on the determination to operate either i) the first sub-photodetector only or ii) both of the first sub-photodetector and the second sub-photodetector; providing pulse signals generated from at least one of the first sub-photodetector or the second sub-photodetector to a read-out circuit to allow the read-out circuit to generate pixel data; and determining a distance to the target object based on the pixel data.

In some implementations, in response to the determination that the distance to the target object is less than the predetermined distance, the switch is turned off and the first pulse signal generated from the first sub-photodetector is provided to the read-out circuit.

In some implementations, in response to the determination that the distance to the target object is greater than the predetermined distance, the switch is turned on and the second pulse signal generated from the first sub-photodetector and the second sub-photodetector is provided to the read-out circuit.

In another aspect, a method of operating an imaging device is provided. The method comprises: making a determination whether a illuminance of an environment external to the imaging device is higher or equal to a predetermined illuminance; turning off or on a switch disposed between a first sub-photodetector and a second sub-photodetector that are included in the imaging device based on the determination to operate either i) the first sub-photodetector only or ii) both of the first sub-photodetector and the second sub-photodetector; providing pulse signals generated from at least one of the first sub-photodetector or the second sub-photodetector to a read-out circuit; and generating pixel data based on the pulse signals.

In some implementations, in response to the determination that the illuminance is higher or equal to a predetermined illuminance, the switch is turned off and the first pulse signal generated from the first sub-photodetector is provided to the read-out circuit, and in response to the determination that illuminance is lower than the predetermined illuminance, the switch is turned on and the second pulse signal generated from the first sub-photodetector and the second sub-photodetector is provided to the read-out circuit.

Although various implementations have been described with reference to the exemplified drawings, variations and improvements of the disclosed embodiments and other embodiments may be made based on what is described or illustrated in this document.

1. An image sensing device comprising:
a substrate; and
a photodetector supported by the substrate and structured to comprise a first semiconductor area and a second semiconductor area surrounding the first semiconductor area,
wherein the first semiconductor area includes a first sub-semiconductor area and a second sub-semiconductor area spaced apart from the first sub-semiconductor area, and
wherein the first sub-semiconductor area and the second sub-semiconductor area are doped with a same conductivity type, and the second semiconductor area is doped with a different conductivity type from the first semiconductor area.

2. The image sensing device of claim 1, wherein a separation distance between the first sub-semiconductor area and the second semiconductor area is greater than a separation distance between the second sub-semiconductor area and the second semiconductor area.

3. The image sensing device of claim 1, wherein the photodetector further comprises an intermediate area that is disposed between the first sub-semiconductor area and the second sub-semiconductor area and between the first semiconductor area and the second semiconductor area.

4. The image sensing device of claim 1, wherein the photodetector further comprises an intermediate area that is disposed between the first sub-semiconductor area and the second sub-semiconductor area, between the second sub-semiconductor area and the second semiconductor area, and between the first semiconductor area and the second semiconductor area.

5. The image sensing device of claim 1, wherein the photodetector comprises a single photon avalanche diode.

6. The image sensing device of claim 1, further comprising:
an analog quenching transistor connected to the photodetector to turn on or off power to the photodetector,
an additional photodetector, and
a switch coupled between the photodetector and the additional photodetector to turn or off a connection between the photodetector and the additional photodetector.

7. The image sensing device of claim 6, wherein the additional photodetector is connected to the analog quenching transistor in response to the switch being turned on, and is not connected to the analog quenching transistor in response to the switch being turned off.

8. The image sensing device of claim 6, wherein a cathode electrode of the photodetector is connected to the first sub-semiconductor area, and a cathode electrode of the additional photodetector is connected to the second sub-semiconductor area.

9. The image sensing device of claim 6, further comprising:
a read-out transistor connected to the photodetector; and
a read-out circuit connected to the read-out transistor.

10. The image sensing device of claim 9, wherein in response to the switch being turned off, a first pulse signal generated from the photodetector is provided to the read-out circuit through the read-out transistor, and in response to the switch being turned on, the first pulse signal and a second pulse signal generated from the additional photodetector are provided to the read-out circuit through the read-out transistor.

11. An imaging device, comprising:
an image sensing device including a pixel comprising a first photodetector and a second photodetector, and a switch coupled to the first photodetector to turn on or off a connection between the first and second photodetectors, wherein each of the first photodetector and the second photodetector comprises a first semiconductor area and a second semiconductor area surrounding the first semiconductor area, and the first semiconductor area includes a first sub-semiconductor area and a second sub-semiconductor area spaced apart from the first sub-semiconductor area;
an image signal processor coupled to the image sensing device to receive pixel data from the pixel of the image sensing device and configured to process pixel data generated from the image sensing device; and
a switch controller,
wherein the pixel of the image sensing device further comprises an analog quenching transistor connected to the photodetector, and a switch turned on or off by the switch controller and arranged between the first photodetector and the second photodetector.

12. The imaging device of claim 11, wherein the switch is turned on or off based on a distance to a target object determined based on the pixel data.

13. The imaging device of claim 11, further comprising:
an illuminance sensor,
wherein the switch is turned on or off based on an illuminance of an environment external to the imaging device and determined by the illuminance sensor.

14. The imaging device of claim 11, wherein the first sub-semiconductor area and the second sub-semiconductor area are doped with a same conductivity type, and the second semiconductor area is doped with a different conductivity type from the first semiconductor area.

15. The imaging device of claim 11, wherein the photodetector comprises a single photon avalanche diode.

16. A method of operating an imaging device, comprising:
making a determination whether a distance to a target object is greater than or equal to a predetermined distance;
turning off or on a switch disposed between a first sub-photodetector and a second sub-photodetector that are included in the imaging device based on the determination to operate either i) the first sub-photodetector only or ii) both of the first sub-photodetector and the second sub-photodetector;
providing pulse signals generated from at least one of the first sub-photodetector or the second sub-photodetector to a read-out circuit to allow the read-out circuit to generate pixel data; and
determining a distance to the target object based on the pixel data.

17. The method of operating the imaging device of claim 16, wherein in response to the determination that the distance to the target object is less than the predetermined distance, the switch is turned off and the first pulse signal generated from the first sub-photodetector is provided to the read-out circuit.

18. The method of operating the imaging device of claim 16, wherein in response to the determination that the distance to the target object is greater than the predetermined distance, the switch is turned on and the second pulse signal generated from the first sub-photodetector and the second sub-photodetector is provided to the read-out circuit.

19. A method of operating an imaging device comprising:
making a determination whether a illuminance of an environment external to the imaging device is higher or equal to a predetermined illuminance;
turning off or on a switch disposed between a first sub-photodetector and a second sub-photodetector that are included in the imaging device based on the determination to operate either i) the first sub-photodetector only or ii) both of the first sub-photodetector and the second sub-photodetector;
providing pulse signals generated from at least one of the first sub-photodetector or the second sub-photodetector to a read-out circuit; and
generating pixel data based on the pulse signals.

20. The method of operating the imaging device of claim 19, wherein in response to the determination that the illuminance is higher or equal to a predetermined illuminance, the switch is turned off and the first pulse signal generated from the first sub-photodetector is provided to the read-out circuit, and in response to the determination that illuminance is lower than the predetermined illuminance, the switch is turned on and the second pulse signal generated from the first sub-photodetector and the second sub-photodetector is provided to the read-out circuit.
